(19) United States
(12) Patent Application Publication
(10) Pub. No.: US 2025/0044680 A1
(43) Pub. Date: Feb. 6, 2025

(54) MASK INSPECTION DEVICE FOR PHOTOMASKS OF EUV LITHOGRAPHY AND CARRIER ELEMENT FOR USE IN A MASK INSPECTION DEVICE

(71) Applicant: Carl Zeiss SMT GmbH, Oberkochen (DE)

(72) Inventors: Markus Koch, Neu-Ulm (DE); Arne Schob, Jena (DE); Manuel Decker, Jena (DE); Matthias Wald, Jena (DE)

(21) Appl. No.: 18/775,277

(22) Filed: Jul. 17, 2024

(30) Foreign Application Priority Data
Aug. 3, 2023 (DE) 102023120658.3

(51) Int. Cl. G03F 1/84; G03F 1/22; G03F 7/00

(52) U.S. Cl. CPC G03F 1/84; G03F 1/22; G03F 7/70733

(57) ABSTRACT

Disclosed is a mask inspection device for photomasks of EUV lithography. The mask inspection device comprises here a receiving device for a photomask, a light source for illuminating the photomask with an illumination beam, and a detection unit for recording at least regions of the photomask. Furthermore, the mask inspection device comprises at least one beam-shaping element for adapting the illumination beam and at least one stop in the light path between the photomask and the detection unit. The at least one beam-shaping element and the at least one stop are arranged in a fixed spatial relationship to one another on a common carrier element. Also disclosed is the corresponding carrier element.

### CROSS REFERENCE TO RELATED APPLICATIONS

The present application claims the priority of the German patent application DE 10 2023 120 658.3, filed on Aug. 3, 2023, the contents of which is fully incorporated herein by reference.

### TECHNICAL FIELD

This disclosure relates to a mask inspection device for photomasks of EUV lithography and to a carrier element for use in a mask inspection device.

### BACKGROUND

Mask inspection devices are described, for example, in Patrick P. Naulleau, e. a. (2014), “Electro-optical system for scanning microscopy of EUV masks with a high harmonic generation source” (Optics Express) or in US patent application US 2012/0008123 A1.

Such a system essentially comprises a zone plate as a beam-shaping element, which focuses coherent EUV radiation from a light source onto a photomask arranged on a displaceable receiving device, and a detection unit for recording an image of the photomask. By means of a stop upstream of the detection unit, it is possible to set the illumination setting of the imaging in particular with regard to the situation when using the photomask in a specific projection exposure apparatus in order to obtain the most realistic assessment as possible of the effect of the photomask during the production operation of semiconductor devices.

In this context, the spatial relationship between the beam-shaping element, the photomask, the stop and the detector is essential.

However, a first problem is that the azimuth of the chief ray of the illumination beam varies over the lateral extent of the photomask due to the non-telecentric design of the associated projection exposure apparatus. Since, in particular, shading effects on the photomask depend on the illumination direction, there is a significant effect on the imaging in the projection exposure apparatus and it is desirable to emulate this effect also during the examination of the photomask in the mask inspection device. In prior-art mask inspection devices, this is achieved, for example, by shifting sigma and NA stops.

### SUMMARY

However, the present inventors have recognized that a single zone plate is only ever designed for one specific illumination direction. Oblique illumination, such as would be required to change the chief ray direction on the photomask, would result in intolerable aberrations.

Furthermore, the illumination setting in the projection exposure apparatus can be emulated via a segmented detector, which can also be designed as a camera; however, this solution is technically complex and comparatively expensive. Alternatively, the illumination setting can also be realized by a stop upstream of a detection unit designed as a photodiode or a photodiode array. This is easier from a detector point of view, but requires a complex mechanism for changing and positioning the stop.

In addition, for a realistic reproduction of the conditions in a projection exposure apparatus, the illumination setting must be centered to the numerical aperture of the corresponding imaging optical unit, i.e. the chief ray of the illumination must be identical to the chief ray of the imaging optical unit. Decentration leads to aberrations such as a shift of the aerial image through the focus. For the mask inspection device described, it is therefore necessary to position the detection unit with great accuracy.

Accordingly, the present disclosure is directed to a mask inspection device for EUV photomasks and an element which, with justifiable technical effort, provide(s) the best possible emulation of the conditions in a projection exposure apparatus.

In one aspect, disclosed is a mask inspection device for photomasks of EUV lithography comprising
a receiving device for a photomask
a light source for illuminating the photomask with an illumination beam
a detection unit for recording at least regions of the photomask
at least one beam-shaping element for adapting the illumination beam
at least one stop in the light path between the photomask and the detection unit.

According to this aspect, the at least one beam-shaping element and the at least one stop are arranged in a fixed spatial relationship to one another on a common carrier element. This allows an optimal configuration of the beam-shaping element and the stop to be defined in advance for a specific measurement situation, and there is no more need for complex adjustment of the two elements relative to each other in the mask inspection device.

In another aspect, disclosed is a carrier element having at least one beam-shaping element and at least one stop for a mask inspection device for photomasks of EUV lithography, wherein the at least one beam-shaping element and the at least one stop are arranged in a fixed spatial relationship to one another on the carrier element.

The disclosed aspects may include any of the following features.

A simple production of the common carrier element can be achieved in that it is designed as a lithographically processed plate.

In particular, the at least one beam-shaping element may be designed as a diffraction structure, which is, for example, inscribed in the carrier element by a lithographic process.

In an advantageous variant, the at least one beam-shaping element is designed as a Fresnel zone plate; further, the at least one stop can be designed as a sigma stop.

An adaptation to the respective measurement positions and illumination settings can be achieved in that a plurality of stops and beam-shaping elements are arranged in pairs which are permanently assigned to one another on the carrier element.

In particular, pairs of beam-shaping elements and stops may be arranged in rows and columns on the carrier element.

For example, it is possible for one specific stop shape to be selected in each case for individual rows, which corresponds to a specific illumination setting. Furthermore, a specific shape of a beam-shaping element and a specific spatial arrangement of the beam-shaping element and the stop can be selected in each case for individual columns. In particular, five or more such columns may be present on the carrier element.

For the recording of the respective photomask, the row which corresponds to the respectively selected illumination setting is first moved into the beam path. Depending on the position of the viewed region on the photomask, in particular the position of the viewed region in the direction of the profile of the scanner slot in the respective associated projection exposure apparatus, those corresponding combinations of beam-shaping element and spatial assignment of beam-shaping element and stop which correspond most closely to the respective chief ray direction are then selected within this row.

In particular, the shape of the beam-shaping element can also change from column to column.

This takes into account the fact that in a projection exposure apparatus the scanner slot naturally has a considerable lateral extent, as a result of which the chief ray direction changes.

To realize the movement of the carrier element required for this, the mask inspection device may comprise a device for positioning the carrier element in two directions perpendicular to each other.

The detector unit can be comparatively simple in design, for example designed as a large-area photodiode. It is advantageous here if the surface area of the photodiode is at least as large as the sigma stop. For example, at a distance of 10 mm between the photomask and the stop and a numerical aperture of 0.1, a diameter of the detection surface of the photodiode of 2 mm would make sense.

Other aspects, embodiments, and advantages follow.

### DESCRIPTION OF DRAWINGS

In the following, embodiments and variants are explained in more detail using the drawing. In the figures,

FIG. 1 shows a basic illustration of an embodiment, and

FIG. 2 shows a schematic illustration of an exemplary carrier element.

### DETAILED DESCRIPTION

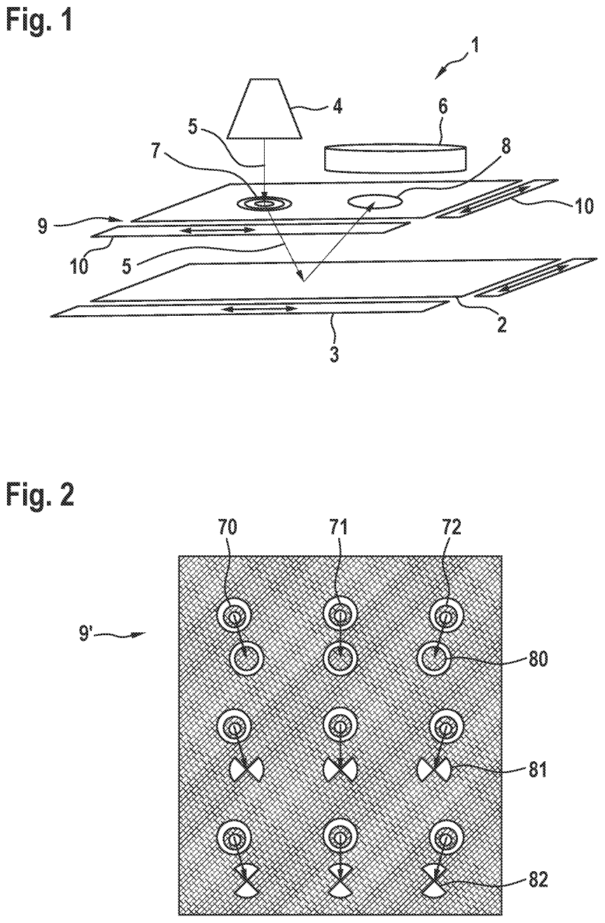

FIG. 1 shows a schematic illustration of a mask inspection device 1. The mask inspection device 1 shown comprises a light source 4, which illuminates a specific region on a photomask 2 by means of an illumination beam 5.

The light coming from the illuminated photomask 2 is detected by a detection unit 6 and supplied to a further evaluation unit (not shown in the figure) for generating an image of the photomask 2.

The surface of the photomask 2 is acquired in regions, i.e. the photomask 2 can be moved to record individual regions of its surface within its own mask plane in two mutually perpendicular directions on a receiving device 3, so that regions of interest on the photomask 2 are illuminated and recorded. The movement of the photomask 2 for positioning is illustrated in FIG. 1 by the two unmarked double-headed arrows.

Between the photomask 2 and the light source 4 or the detector unit 6, a carrier element 9 is arranged, on which a plurality of pairs of a beam-shaping unit, designed as a Fresnel zone plate 7 in the example shown, and stops implemented as sigma stops 8 are arranged in a fixed spatial relationship to one another. For reasons of clarity, only a single pair is shown in FIG. 1.

The illumination beam 5 passes through the zone plate 7 and is focused thereby at the desired region of the photomask 2. Starting from the photomask 2, the radiation reflected at it passes through the sigma stop 8 and is then incident on the detector unit 6, which can be designed, for example, as a large-area photodiode.

It is clear in the figure that by using the carrier element 9 with the beam-shaping element 7 arranged thereon and the stop 8, a fixed spatial reference between the two elements 7, 8 mentioned last can be produced in a comparatively simple manner. In particular using the solution shown, a corresponding carrier element with the elements arranged thereon can be prepared outside the mask inspection device 1 and subsequently be placed therein, wherein the spatial reference of the beam-shaping unit 7 and the stop 8 is maintained due to the monolithic solution shown.

In general, it is desirable to be able to easily emulate different illumination settings and chief ray directions in a mask inspection device. For this reason, the carrier unit 9 is arranged on a device 10 for positioning, by means of which the matching pair for the respective setting/the respective chief ray direction can be introduced into the beam path. The corresponding movement directions are shown in FIG. 2 by arrows which not specifically marked.

FIG. 2 shows a schematic illustration of an exemplary carrier element 9′. On the carrier element 9′ shown in FIG. 2, a total of nine pairs of Fresnel zone plates 70, 71, 72 and sigma stops 80, 81, 82 are arranged in three rows and three columns. The same sigma stops 80, 81, 82 are used within a row, and the same Fresnel zone plates 70, 71, 72 are used within a column. Likewise, the relative arrangements of the zone plate and the sigma stop within the respective pairs within a column correspond to one another.

During operation of the associated mask inspection device 1, the illumination setting for which the photomask 2 currently being investigated is to be measured is first selected by selecting the respective row. In other words, the shape of the sigma stop 80, 81 or 82 is first selected. During the measurement process, depending on the position of the region currently being investigated on the photomask 2, the pair of zone plate and sigma stop which best maps the conditions in a projection exposure apparatus for the region being investigated is then selected.

In other words, the selection of the column corresponding to the region being considered simulates the associated chief ray direction (presented in the figure by unmarked arrows). It goes without saying that a division into three columns and thus into three different chief ray directions as shown in the figure will not meet the requirements in all cases. It is to be assumed that five or more columns or chief ray directions are required.

In practice, it is necessary to find a compromise between the fineness of the division into different chief ray directions and the total time required to shift the carrier element 9′ for changing the column.

Additional embodiments are within the scope of the following claims.

### LIST OF REFERENCE SIGNS

1 Mask inspection device
2 Photomask
3 Receiving device
4 Light source
5 Illumination beam
6 Detection unit
7 Beam-shaping unit
8 Stop
9, 9′ Carrier element
10 Device for positioning
70, 71, 72 Fresnel zone plates
80, 81, 82 Sigma stops

What is claimed is:

1. A mask inspection device for photomasks of EUV lithography,
comprising
a receiving device for a photomask
a light source for illuminating the photomask with an illumination beam
a detection unit for recording at least regions of the photomask
at least one beam-shaping element for adapting the illumination beam
at least one stop in the light path between the photomask and the detection unit
wherein
the at least one beam-shaping element and the at least one stop are arranged in a fixed spatial relationship to one another on a common carrier element.

2. The mask inspection device of claim 1,
wherein
the common carrier element is designed as a lithographically processed plate.

3. The mask inspection device of claim 1,
wherein
at least one beam-shaping element is designed as a diffraction structure.

4. The mask inspection device of claim 3,
wherein
the at least one beam-shaping element is designed as a Fresnel zone plate.

5. The mask inspection device of claim 1,
wherein
the at least one stop is designed as a sigma stop.

6. The mask inspection device of claim 1,
wherein
a plurality of stops and beam-shaping elements are arranged in pairs which are permanently assigned to one another on the carrier element.

7. The mask inspection device of claim 1,
wherein
pairs of beam-shaping elements and stops are arranged in rows and columns on the carrier element.

8. The mask inspection device of claim 7,
wherein
one specific stop shape is selected in each case for individual rows.

9. The mask inspection device of claim 7,
wherein
a specific shape of a beam-shaping element and a specific spatial arrangement of the beam-shaping element and the stop is selected in each case for individual columns.

10. The mask inspection device of claim 7,
wherein
the carrier element has at least five columns.

11. The mask inspection device of claim 1,
wherein
the mask inspection device comprises a device for positioning the carrier element in two directions perpendicular to each other.

12. The mask inspection device of claim 1,
wherein
the detector unit is designed as a large-area photodiode.

13. A carrier element having at least one beam-shaping element and at least one stop for a mask inspection device for photomasks of EUV lithography, wherein the at least one beam-shaping element and the at least one stop are arranged in a fixed spatial relationship to one another on the carrier element.

14. The carrier element of claim 13,
wherein
the carrier element is designed as a lithographically processed plate.

15. The carrier element of claim 13,
wherein
at least one beam-shaping element is designed as a diffraction structure.

16. The carrier element of claim 15,
wherein
the at least one beam-shaping element is designed as a Fresnel zone plate.

17. The carrier element of claim 13,
wherein
the at least one stop is designed as a sigma stop.

18. The carrier element of claim 13,
wherein
a plurality of stops and beam-shaping elements are arranged in pairs which are permanently assigned to one another on the carrier element.

19. The carrier element of claim 13,
wherein
pairs of beam-shaping elements and stops are arranged in rows and columns on the carrier element.

20. The carrier element of claim 19,
wherein
one specific stop shape is selected in each case for individual rows.

21. The carrier element of claim 19,
wherein
a specific shape of a beam-shaping element and a specific spatial arrangement of the beam-shaping element and the stop is selected in each case for individual columns.

22. The carrier element of claim 19,
wherein
the carrier element has at least five columns.
